(19) United States
(12) Patent Application Publication
(10) Pub. No.: US 2026/0059968 A1
(43) Pub. Date: Feb. 26, 2026

(54) DISPLAY APPARATUS AND METHOD OF MANUFACTURING THE SAME

(71) Applicant: Samsung Display Co., Ltd., Yongin-si (KR)

(72) Inventors: Chaungi Choi, Yongin-si (KR); Geebum Kim, Yongin-si (KR); Hyoengki Kim, Yongin-si (KR); Bokwang Song, Yongin-si (KR); Hyeonbum Lee, Yongin-si (KR)

(21) Appl. No.: 19/305,563

(22) Filed: Aug. 20, 2025

(30) Foreign Application Priority Data
Aug. 21, 2024 (KR) 10-2024-0112337

(51) Int. Cl. H10K 59/80; H10K 59/12; H10K 102/00

(52) U.S. Cl. CPC H10K 59/80515; H10K 59/1201; H10K 2102/331

(57) ABSTRACT

A display apparatus includes a substrate, and a pixel electrode above the substrate and including a first pixel electrode above the substrate, and having a bottom surface that is flat, a second pixel electrode above the first pixel electrode, and having a top surface that has an uneven shape, and a third pixel electrode above the second pixel electrode, and having a top surface that has an uneven shape.

### CROSS-REFERENCE TO RELATED APPLICATION

The present application claims priority to, and the benefit of, Korean Patent Application No. 10-2024-0112337, filed on Aug. 21, 2024, in the Korean Intellectual Property Office, the entire disclosure of which is incorporated herein by reference.

### BACKGROUND

### 1. Field

One or more embodiments relate to a display apparatus and a method of manufacturing the same.

### 2. Description of the Related Art

Display apparatuses visually display data. Display apparatuses are used as displays for small products, such as mobile phones, or are used as displays for large products, such as televisions.

A display apparatus includes a plurality of pixels that emit light by receiving an electrical signal to display an image to the outside. Each pixel includes a display element. For example, an organic light-emitting display apparatus includes an organic light-emitting diode (OLED) as a display element. In general, an organic light-emitting display apparatus includes a thin-film transistor and an OLED formed on a substrate, and the OLED emits light.

As display apparatuses have recently been used for various purposes, various designs have been attempted to improve the quality of display apparatuses.

### SUMMARY

One or more embodiments include a display apparatus with improved reliability and quality and a method of manufacturing the display apparatus. However, the embodiments are examples and do not limit the scope of the disclosure.

Additional aspects will be set forth in part in the description which follows and, in part, will be apparent from the description, or may be learned by practice of the presented embodiments.

According to one or more embodiments, a display apparatus includes a substrate, and a pixel electrode above the substrate and including a first pixel electrode above the substrate, and having a bottom surface that is flat, a second pixel electrode above the first pixel electrode, and having a top surface that has an uneven shape, and a third pixel electrode above the second pixel electrode, and having a top surface that has an uneven shape.

A bottom surface of the second pixel electrode may have an uneven shape.

The display apparatus may further include metal nanoparticles distributed on the bottom surface of the second pixel electrode to form the uneven shape.

A diameter of the metal nanoparticles may be tens of nm to several μm.

The first pixel electrode may include a transparent electrode.

The third pixel electrode may include a transparent electrode.

The second pixel electrode may include a metal.

The second pixel electrode may include silver (Ag).

According to one or more embodiments, a method of manufacturing a display apparatus includes arranging a first pixel electrode material above a substrate, arranging metal nanoparticles above the first pixel electrode material, arranging a second pixel electrode material above the metal nanoparticles, arranging a third pixel electrode material above the second pixel electrode-forming material, and forming a first pixel electrode, a second pixel electrode, and a third pixel electrode by etching the first pixel electrode material, the second pixel electrode material, and the third pixel electrode material.

The metal nanoparticles may be distributed on a bottom surface of the second pixel electrode material to form an uneven shape.

The arranging of the metal nanoparticles on the first pixel electrode material may include arranging a metal nanoparticle material on the first pixel electrode material, and forming the metal nanoparticles on a top surface of the first pixel electrode material by heat-treating the metal nanoparticle-forming material.

The heat-treating the metal nanoparticle material may cause the metal nanoparticle material to aggregate to form nanoparticles.

A top surface of the second pixel electrode material may have an uneven shape.

A top surface of the third pixel electrode material may have an uneven shape.

A bottom surface of the first pixel electrode material may have a flat shape.

The first pixel electrode material may include a transparent electrode material.

The metal nanoparticle material and the second pixel electrode material may include a same material.

The second pixel electrode material may include a metal.

The third pixel electrode material may include a transparent electrode material.

According to one or more embodiments, an electronic device includes a display apparatus including a substrate, and a pixel electrode above the substrate and including a first pixel electrode above the substrate, and having a bottom surface that is flat, a second pixel electrode above the first pixel electrode, and having a top surface that has an uneven shape, and a third pixel electrode above the second pixel electrode, and having a top surface that has an uneven shape.

### BRIEF DESCRIPTION OF THE DRAWINGS

The above and other aspects of certain embodiments will be more apparent from the following description taken in conjunction with the accompanying drawings, in which:

FIGS. 1A and 1B are perspective views schematically illustrating a display apparatus, according to one or more embodiments;

FIGS. 2A and 2B are equivalent circuit diagrams schematically illustrating a light-emitting diode corresponding to any one sub-pixel of a display apparatus and a sub-pixel circuit electrically connected to the light-emitting diode, according to one or more embodiments;

FIG. 3 is a cross-sectional view schematically illustrating a display panel, according to one or more embodiments;

FIG. 4 is an enlarged cross-sectional view schematically illustrating a display panel, according to one or more embodiments;

FIGS. 5 to 9 are cross-sectional views schematically illustrating a method of manufacturing a display panel, according to one or more embodiments;

FIG. 10 is a graph schematically illustrating a luminance according to a viewing angle, according to a comparative example and one or more embodiments; and FIG. 11 is a graph schematically illustrating color coordinates according to a viewing angle, according to a comparative example and one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B”may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),”etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

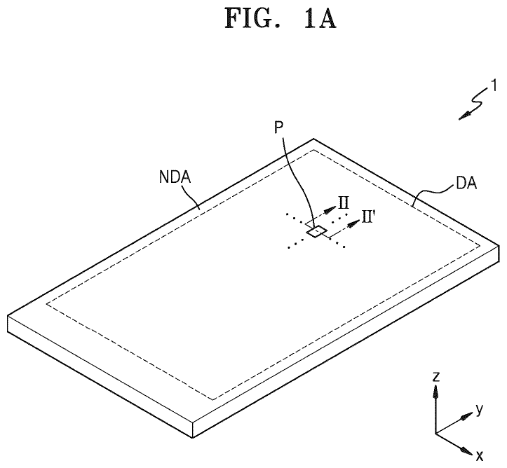

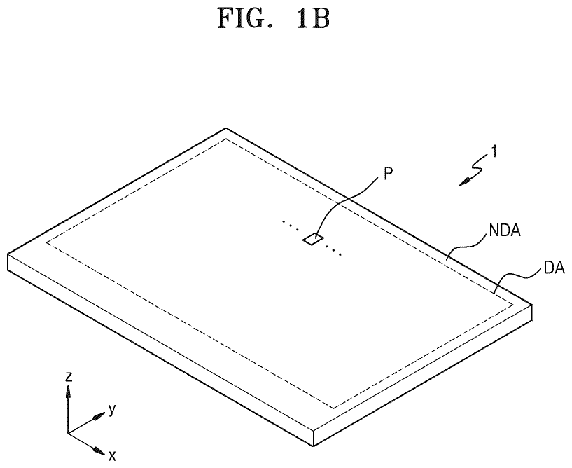

FIGS. 1A and 1B are perspective views schematically illustrating a display apparatus, according to one or more embodiments.

Referring to FIGS. 1A and 1B, a display apparatus 1 may include a display area DA, and a non-display area NDA located outside the display area DA. The display area DA may display an image through sub-pixels P located in the display area DA. The non-display area NDA, which is located outside the display area DA and does not display an image, may entirely surround the display area DA (e.g., in plan view). A driver or the like for applying an electrical signal or power to the display area DA may be located in the non-display area NDA. A pad to which an electronic device or a printed circuit board may be electrically connected may be located in the non-display area NDA.

Although the display area DA has a polygonal shape (e.g., a quadrangular shape) in which a length in an x-direction is less than a length in a y-direction in FIG. 1A, in one or more other embodiments, the display area DA may have a polygonal shape (e.g., a quadrangular shape) in which a length in the y-direction is less than a length in the x-direction, as shown in FIG. 1B. Although the display area DA has a substantially quadrangular shape in FIGS. 1A and 1B, the disclosure is not limited thereto. In one or more other embodiments, the display area DA may have any of various shapes, such as an N-gon shape (where N is a natural number of 3 or more), a circular shape, or an elliptical shape. Although the display area DA has a shape with corners where straight lines meet each other in FIGS. 1A and 1B, in one or more other embodiments, the display area DA may have a polygonal shape with rounded corners.

Although the display apparatus 1 is an electronic device that is a smartphone for convenience of explanation, the display apparatus 1 is not limited thereto. The display apparatus 1 may be applied to any of various products, such as a television, a laptop computer, a monitor, an advertisement board, or an Internet of things (IoT) product as well as a portable electronic device, such as a mobile phone, a smartphone, a tablet personal computer (PC), a mobile communication terminal, an electronic organizer, an electronic book, a portable multimedia player (PMP), a navigation device, or an ultra-mobile PC (UMPC). Also, the display apparatus 1 according to one or more embodiments may be applied to a wearable device, such as a smart watch, a watch phone, a glasses-type display, or a head-mounted display (HMD). Also, the display apparatus 1 according to one or more embodiments may be applied to a center information display (CID) located on an instrument panel, a center fascia, or a dashboard of a vehicle, a room mirror display replacing a side-view mirror of a vehicle, or a display screen located on the back of a front seat for entertainment for a person in a back seat of a vehicle.

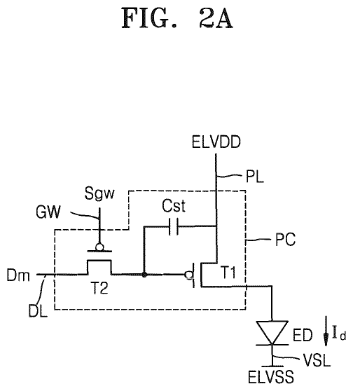

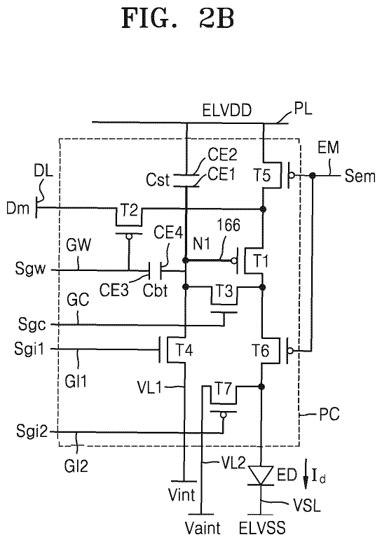

FIGS. 2A and 2B are equivalent circuit diagrams schematically illustrating a light-emitting diode corresponding to any one sub-pixel of a display apparatus and a sub-pixel circuit electrically connected to the light-emitting diode, according to one or more embodiments.

Referring to FIG. 2A, a light-emitting diode ED may be electrically connected to a sub-pixel circuit PC, and the sub-pixel circuit PC may include a first transistor T1, a second transistor T2, and a storage capacitor Cst. A sub-pixel electrode (e.g., an anode) of the light-emitting diode ED may be electrically connected to the first transistor T1, and a counter electrode (e.g., a cathode) may be electrically connected to an auxiliary wiring VSL, and may receive a voltage corresponding to a common voltage ELVSS through the auxiliary wiring VSL.

The second transistor T2 transmits a data signal Dm input through a data line DL according to a scan signal Sgw input through a scan line GW to the first transistor T1.

The storage capacitor Cst is connected to the second transistor T2 and a driving voltage line PL, and stores a voltage corresponding to a difference between a voltage received from the second transistor T2 and a driving voltage ELVDD supplied to the driving voltage line PL.

The first transistor T1 may be connected to the driving voltage line PL and the storage capacitor Cst, and may control driving current I_{d} flowing through the light-emitting diode ED from the driving voltage line PL in response to a value of the voltage stored in the storage capacitor Cst. The light-emitting diode ED may emit light having a certain luminance due to the driving current I_{d}.

Although the sub-pixel circuit PC includes two transistors and one storage capacitor in FIG. 2A, the disclosure is not limited thereto.

FIG. 2B is an equivalent circuit diagram schematically illustrating a light-emitting diode corresponding to any one sub-pixel of a display apparatus and a sub-pixel circuit electrically connected to the light-emitting diode, according to one or more other embodiments.

Referring to FIG. 2B, a sub-pixel circuit PC may include seven thin-film transistors and two capacitors.

The sub-pixel circuit PC may include first to seventh transistors T1, T2, T3, T4, T5, T6, and T7, a storage capacitor Cst, and a boost capacitor Cbt. In one or more other embodiments, the sub-pixel circuit PC may omit the boost capacitor Cbt. A sub-pixel electrode (e.g., an anode) of a light-emitting diode ED may be electrically connected to the first transistor T1 via the sixth transistor T6, and a counter electrode (e.g., a cathode) may be electrically connected to an auxiliary wiring VSL, and may receive a voltage corresponding to a common voltage ELVSS through the auxiliary wiring VSL.

Some of the first to seventh transistors T1 to T7 may be n-channel MOSFETs (NMOSs) and the rest may be p-channel MOSFETs (PMOSs). In one or more embodiments, as shown in FIG. 2B, the third and fourth transistors T3 and T4 may be NMOSs, and the rest may be PMOSs. For example, the third and fourth transistors T3 and T4 may be NMOSs including an oxide-based semiconductor material, and the rest may be PMOSs including a silicon-based semiconductor material. In one or more other embodiments, the third, fourth, and seventh transistors T3, T4, and T7 may be NMOSs, and the rest may be PMOSs.

The first to seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The sub-pixel circuit PC may be electrically connected to voltage lines, for example, a driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a first electrode (e.g., an anode) of the light-emitting diode ED via the sixth transistor T6. One of the first electrode and the second electrode of the first transistor T1 may be a source electrode, and the other may be a drain electrode. The first transistor T1 may supply driving current I_{d} to the light-emitting diode ED according to a switching operation of the second transistor T2.

The second transistor T2 may be a switching transistor. A second gate electrode of the second transistor T2 is connected to the scan line GW, a first electrode of the second transistor T2 is connected to the data line DL, and a second electrode of the second transistor T2 is connected to the driving first electrode of the first transistor T1, and is electrically connected to the driving voltage line PL via the fifth transistor T5. One of the first electrode and the second electrode of the second transistor T2 may be a source electrode, and the other may be a drain electrode. The second transistor T2 may be turned on according to a scan signal Sgw received through the scan line GW, and may perform a switching operation of transmitting a data signal Dm transmitted through the data line DL to the first electrode of the first transistor T1.

The third transistor T3 may be a compensation transistor for compensating for a threshold voltage of the first transistor T1. A third gate electrode of the third transistor T3 is connected to the compensation gate line GC. A first electrode of the third transistor T3 is connected to a lower electrode CE1 of the storage capacitor Cst and to the first gate electrode of the first transistor T1 through a node connection line 166. The first electrode of the third transistor T3 may be connected to the fourth transistor T4. A second electrode of the third transistor T3 is connected to the second electrode of the first transistor T1, and is electrically connected to the first electrode (e.g., the anode) of the light-emitting diode ED via the sixth transistor T6. One of the first electrode and the second electrode of the third transistor T3 may be a source electrode, and the other may be a drain electrode.

The third transistor T3 is turned on according to a compensation signal Sgc received through the compensation gate line GC to diode-connect the first transistor T1 by electrically connecting the first gate electrode and the second electrode (e.g., drain electrode) of the first transistor T1.

The fourth transistor T4 may be a first initialization transistor that initializes the first gate electrode of the first transistor T1. A fourth gate electrode of the fourth transistor T4 is connected to the first initialization gate line GI1. A first electrode of the fourth transistor T4 is connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode, and the other may be a drain electrode. The fourth transistor T4 may be turned on according to a first initialization signal Sgi1 received through the first initialization gate line GI1, and may perform an initialization operation of initializing a voltage of the first gate electrode of the first transistor T1 by transmitting a first initialization voltage Vint to the first gate electrode of the first transistor T1.

The fifth transistor T5 may be an operation control transistor. A fifth gate electrode of the fifth transistor T5 is connected to the emission control line EM, a first electrode of the fifth transistor T5 is connected to the driving voltage line PL, and a second electrode of the fifth transistor T5 is connected to the driving first electrode of the first transistor T1 and to the second electrode of the second transistor T2. One of the first electrode and the second electrode of the fifth transistor T5 may be a source electrode, and the other may be a drain electrode.

The sixth transistor T6 may be an emission control transistor. A sixth gate electrode of the sixth transistor T6 is connected to the emission control line EM, a first electrode of the sixth transistor T6 is connected to the second electrode of the first transistor T1 and to the second electrode of the third transistor T3, and a second electrode of the sixth transistor T6 is electrically connected to a second electrode of the seventh transistor T7 and to the first electrode (e.g., the anode) of the light-emitting diode ED. One of the first electrode and the second electrode of the sixth transistor T6 may be a source electrode, and the other may be a drain electrode.

The fifth transistor T5 and the sixth transistor T6 may be concurrently or substantially simultaneously turned on according to an emission control signal Sem received through the emission control line EM so that a driving voltage ELVDD is transmitted to the light-emitting diode ED and the driving current I_{d} flows through the light-emitting diode ED.

The seventh transistor T7 may be a second initialization transistor for initializing the first electrode (e.g., the anode) of the light-emitting diode ED. A seventh gate electrode of the seventh transistor T7 is connected to the second initialization gate line GI2. A first electrode of the seventh transistor T7 is connected to the second initialization voltage line VL2. The second electrode of the seventh transistor T7 is connected to the second electrode of the sixth transistor T6 and to the first electrode (e.g., the anode) of the light-emitting diode ED. The seventh transistor T7 may be turned on according to a second initialization signal Sgi2 received through the second initialization gate line GI2 so that a second initialization voltage Vaint is transmitted to the first electrode (e.g., the anode) of the light-emitting diode ED, and the first electrode of the light-emitting diode ED is initialized.

In some embodiments, the second initialization gate line GI2 may be a next scan line. For example, the second initialization gate line GI2 connected to the seventh transistor T7 of the sub-pixel circuit PC located in an i^{th} row (i is a natural number) may correspond to a scan line of the sub-pixel circuit PC located in an (i+1)^{th} row. In one or more other embodiments, the second initialization voltage line VL2 may be the emission control line EM. For example, the emission control line EM may be electrically connected to the fifth to seventh transistors T5, T6, and T7.

The storage capacitor Cst includes the lower electrode CE1 and an upper electrode CE2. The lower electrode CE1 of the storage capacitor Cst is connected to the first gate electrode of the first transistor T1, and the upper electrode CE2 of the storage capacitor Cst is connected to the driving voltage line PL. The storage capacitor Cst may store a charge corresponding to a difference between a voltage of the first gate electrode of the first transistor T1 and the driving voltage ELVDD.

The boost capacitor Cbt includes a third electrode CE3 and a fourth electrode CE4. The third electrode CE3 may be connected to the second gate electrode of the second transistor T2 and to the scan line GW, and the fourth electrode CE4 may be connected to the first electrode of the third transistor T3 and to the node connection line 166. The boost capacitor Cbt may increase a voltage of a first node N1 when the scan signal Sgw supplied through the scan line GW is turned off, and when a voltage of the first node N1 is increased, a black gray scale may be clearly exhibited.

The first node N1 may be an area where the first gate electrode of the first transistor T1, the first electrode of the third transistor T3, the second electrode of the fourth transistor T4, and the fourth electrode CE4 of the boost capacitor Cbt are connected.

In one or more embodiments, in FIG. 2B, the third and fourth transistors T3 and T4 are NMOSs, and the first, second, fifth, sixth, and seventh transistors T1, T2, T5, T6, and T7 are PMOSs. The first transistor T1, which directly affects the brightness of a display apparatus for displaying an image, may include a semiconductor layer formed of polycrystalline silicon having high reliability, thereby making it possible to implement a high-resolution display apparatus.

Although some transistors are NMOSFETs and the rest are PMOSFETs in FIG. 2B, the disclosure is not limited thereto. In one or more other embodiments, various modifications may be made. For example, the sub-pixel circuit PC may include three transistors, and all of the three transistors may be NMOSFETs.

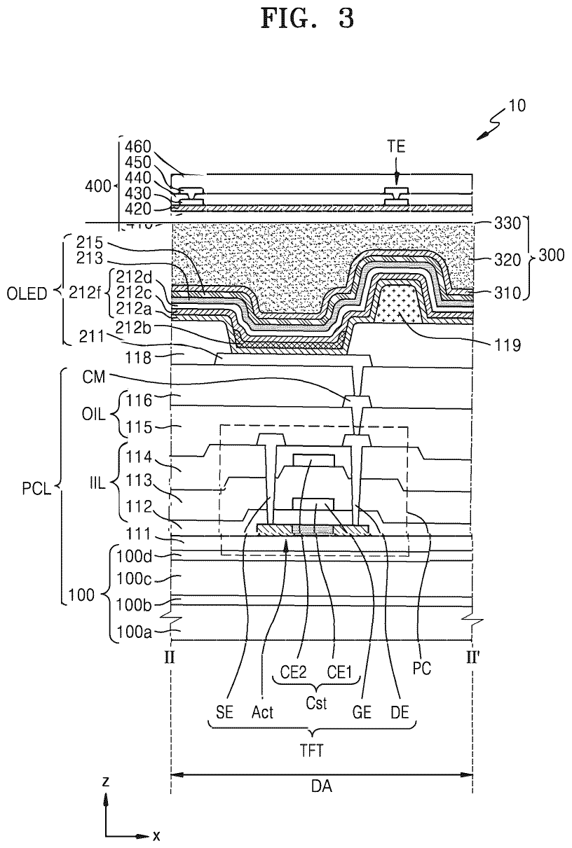

FIG. 3 is a cross-sectional view schematically illustrating a display panel, according to one or more embodiments.

Referring to FIG. 3, a display panel 10 may include a substrate 100, an inorganic insulating layer IIL, an organic insulating layer OIL, a sub-pixel circuit PC, a connection electrode CM, and a pixel electrode 211. That is, the substrate 100, the inorganic insulating layer IIL, the organic insulating layer OIL, the sub-pixel circuit PC, the connection electrode CM, an organic light-emitting diode OLED, a pixel-defining film 118, a spacer 119, and a thin-film encapsulation layer 300 may be located in a display area DA of the display panel 10. A pixel circuit layer PCL may include the substrate 100, the inorganic insulating layer IIL, the organic insulating layer OIL, the sub-pixel circuit PC, and the connection electrode CM.

The substrate 100 may include a first base layer 100a, a first barrier layer 100b, a second base layer 100c, and a second barrier layer 100d. In one or more embodiments, the first base layer 100a, the first barrier layer 100b, the second base layer 100c, and the second barrier layer 100d may be sequentially stacked in a thickness direction of the substrate 100.

At least one of the first base layer 100a and the second base layer 100c may include a polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

Each of the first barrier layer 100b and the second barrier layer 100d, which is a barrier layer for reducing or preventing penetration of an external foreign material, may have a single or multi-layer structure including an inorganic material, such as silicon nitride (SiN_{X}), silicon oxide (SiO₂), and/or silicon oxynitride (SiON).

A buffer layer 111 may be located on the substrate 100 (as used herein, “located on” may mean “above”). The buffer layer 111 may include an inorganic insulating material, such as silicon nitride (SiN_{X}), silicon oxynitride (SiON), or silicon oxide (SiO₂), and may have a single or multi-layer structure including the inorganic insulating material.

The inorganic insulating layer IIL may be located on the buffer layer 111. The inorganic insulating layer IIL may include a first inorganic insulating layer 112, a second inorganic insulating layer 113, and a third inorganic insulating layer 114.

The sub-pixel circuit PC may be located in the display area DA. The sub-pixel circuit PC may include a thin-film transistor TFT and a storage capacitor Cst. The thin-film transistor TFT may include a semiconductor layer Act, a gate electrode GE, a source electrode SE, and a drain electrode DE.

The semiconductor layer Act may be located on the buffer layer 111. The semiconductor layer Act may include polysilicon. Alternatively, the semiconductor layer Act may include amorphous silicon, an oxide semiconductor, or an organic semiconductor. The semiconductor layer Act may include a channel region, and a drain region and a source region located on both sides of the channel region.

The gate electrode GE may be located on the semiconductor layer Act. The gate electrode GE may overlap the channel region. The gate electrode GE may include a low-resistance metal material. The gate electrode GE may include a conductive material including molybdenum (Mo), aluminum (Al), copper (Cu), or titanium (Ti), and may have a single or multi-layer structure including the above material.

The first inorganic insulating layer 122 may be located between the semiconductor layer Act and the gate electrode GE. The first inorganic insulating layer 112 may include an inorganic insulating material, such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second inorganic insulating layer 113 may be located on the gate electrode GE. The second inorganic insulating layer 113 may cover the gate electrode GE. The second inorganic insulating layer 113 may include an inorganic insulating material, such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the storage capacitor Cst may be located on the second inorganic insulating layer 113. The upper electrode CE2 may overlap the gate electrode GE that is located below the upper electrode CE2. In this case, the gate electrode GE and the upper electrode CE2 overlapping each other with the second inorganic insulating layer 113 therebetween may constitute the storage capacitor Cst. That is, the gate electrode GE may function as a lower electrode CE1 of the storage capacitor Cst.

As such, the storage capacitor Cst and the thin-film transistor TFT may overlap each other. However, the disclosure is not limited thereto. For example, the storage capacitor Cst may not overlap the thin-film transistor TFT. That is, the lower electrode CE1 of the storage capacitor Cst is an element separate from the gate electrode GE of the thin-film transistor TFT, and may be spaced apart from the gate electrode GE of the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure including the above material.

The third inorganic insulating layer 114 may be located on the upper electrode CE2. The third inorganic insulating layer 114 may cover the upper electrode CE2. The third inorganic insulating layer 114 may include silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The third inorganic insulating layer 114 may have a single or multi-layer structure including the above inorganic insulating material.

Each of the drain electrode DE and the source electrode SE may be located on the third inorganic insulating layer 114. The drain electrode DE and the source electrode SE may be connected to the semiconductor layer Act through contact holes formed in the first inorganic insulating layer 112, the second inorganic insulating layer 113, and the third inorganic insulating layer 114. Each of the drain electrode DE and the source electrode SE may include a material having good conductivity. Each of the drain electrode DE and the source electrode SE may include a conductive material including molybdenum (Mo), aluminum (Al), copper (Cu), or titanium (Ti), and may have a single or multi-layer structure including the above material. For example, each of the drain electrode DE and the source electrode SE may have a multi-layer structure including Ti/Al/Ti.

The organic insulating layer OIL may be located on the inorganic insulating layer IIL. The organic insulating layer OIL may include a first organic insulating layer 115 and a second organic insulating layer 116. Although two organic insulating layers OIL are provided in FIG. 3, the disclosure is not limited thereto. For example, one, three, or four organic insulating layers OIL may be provided in one or more embodiments.

The first organic insulating layer 115 may cover the drain electrode DE and the source electrode SE. The first organic insulating layer 115 may include an organic insulating material, such as a general-purpose polymer (e.g., polymethyl methacrylate (PMMA) or polystyrene (PS)), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

The connection electrode CM may be located on the first organic insulating layer 115. In this case, the connection electrode CM may be connected to the drain electrode DE or the source electrode SE through a contact hole of the first organic insulating layer 115. The connection electrode CML may include a material having good conductivity. The connection electrode CM may include a conductive material including molybdenum (Mo), aluminum (Al), copper (Cu), or titanium (Ti), and may have a single or multi-layer structure including the above material. For example, the connection electrode CM may have a multi-layer structure including Ti/Al/Ti.

The second organic insulating layer 116 may be located on the connection electrode CM. The second organic insulating layer 116 may cover the connection electrode CM. The second organic insulating layer 116 and the first organic insulating layer 115 may be formed of the same material or different materials.

A light-emitting electrode may be located on the second organic insulating layer 116. For example, the organic light-emitting diode OLED may be located on the second organic insulating layer 116. Alternatively, in one or more other embodiments, an inorganic light-emitting diode may be located on the second organic insulating layer 116.

The organic light-emitting diode OLED may emit red light, green light, or blue light, or may emit red light, green light, blue light, or white light. The organic light-emitting diode OLED may include the pixel electrode 211, an emission layer 212b, a functional layer 212f, a counter electrode 213, and a capping layer 215.

The pixel electrode 211 may be located on the second organic insulating layer 116. The pixel electrode 211 may be electrically connected to the connection electrode CM through a contact hole defined in the second organic insulating layer 116. The pixel electrode 211 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). In one or more embodiments, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In one or more embodiments, the pixel electrode 211 may further include a film formed of ITO, IZO, ZnO, or In₂O₃ over/under the above reflective film. For example, the pixel electrode 211 may have a multi-layer structure including ITO/Ag/ITO.

An emission area where light is emitted from the organic light-emitting diode OLED may be defined on the pixel electrode 211 by an opening through at least a part of the pixel electrode 211 is exposed. For example, a width of the opening may correspond to a width of the emission area.

The pixel-defining film 118 may include an organic insulating material. Alternatively, the pixel-defining film 118 may include an inorganic insulating material, such as silicon nitride, silicon oxynitride, or silicon oxide. Alternatively, the pixel-defining film 118 may include an organic insulating material and an inorganic insulating material. In one or more embodiments, the pixel-defining film 118 may include a light-blocking material. The light-blocking material may include carbon black, carbon nanotubes, a resin or paste including a black dye, metal particles, such as nickel, aluminum, molybdenum, or an alloy thereof, metal oxide particles (e.g., chromium oxide), or metal nitride particles (e.g., chromium nitride). When the pixel-defining film 118 includes the light-blocking material, reflection of external light by metal structures located under the pixel-defining film 118 may be reduced.

The spacer 119 may be located on the pixel-defining film 118. The spacer 119 may include an organic insulating material, such as polyimide. Alternatively, the spacer 119 may include an inorganic insulating material, such as silicon nitride (SiN_{X}) or silicon oxide (SiO2), or may include an organic insulating material and an inorganic insulating material.

In one or more embodiments, the spacer 119 may include the same material as the pixel-defining film 118. In this case, the pixel-defining film 118 and the spacer 119 may be formed together in a mask process using a halftone mask or the like. Alternatively, the spacer 119 and the pixel-defining film 118 may include different materials.

The emission layer 212b may be located in an opening of on the pixel-defining film 118. The emission layer 212b may include a high molecular weight organic material or a low molecular weight organic material emitting light of a certain color.

The functional layer 212f may include a first functional layer 212a, a second functional layer 212c, and a common layer 212d. The first functional layer 212a may be located between the pixel electrode 211 and the emission layer 212b, and the second functional layer 212c may be located between the emission layer 212b and the common layer 212d. The common layer 212d may be located between the second functional layer 212c and the counter electrode 213. However, at least one of the first functional layer 212a, the second functional layer 212c, or the common layer 212d may be omitted. The following will be described in detail assuming that the first functional layer 212a, the second functional layer 212c, and the common layer 212d are respectively located.

The first functional layer 212a may include a hole transport layer (HTL) and/or a hole injection layer (HIL). The second functional layer 212c may include an electron transport layer (ETL). The common layer 212d may include an electron injection layer (EIL). The first functional layer 212a, the second functional layer 212c, and/or the common layer 212d may entirely cover the substrate 100, like the common electrode 213 described below.

The counter electrode 213 may be located on the functional layer 212f. The counter electrode 213 may be formed of a conductive material having a low work function. For example, the counter electrode 213 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 213 may further include a layer formed of ITO, IZO, ZnO, or In₂O₃ on the (semi)transparent layer including the above material.

In one or more embodiments, the capping layer 215 may be located on the counter electrode 213. The capping layer 215 may include LiF, an inorganic material, and/or an organic material.

The thin-film encapsulation layer 300 may be located on the organic light-emitting diode OLED. The thin-film encapsulation layer 300 may cover the organic light-emitting diode OLED. The thin-film encapsulation layer 300 may be located on the counter electrode 213 and/or the capping layer 215. In one or more embodiments, the thin-film encapsulation layer 300 may include at least one inorganic film layer and at least one organic film layer.

In one or more embodiments, the thin-film encapsulation layer 300 may include a first inorganic encapsulation layer 310, an organic encapsulation layer 320, and a second inorganic encapsulation layer 330, which are sequentially stacked. Each of the first and second inorganic encapsulation layers 310 and 330 may include at least one inorganic material from among aluminum oxide, titanium oxide, tantalum oxide, hafnium oxide, zinc oxide, silicon oxide, silicon nitride, or silicon oxynitride. Each of the first inorganic encapsulation layer 310 and the second inorganic encapsulation layer 330 may have a single or multi-layer structure including the above material. The organic encapsulation layer 320 may include a polymer-based material. Examples of the polymer-based material may include an acrylic resin, an epoxy resin, polyimide, and polyethylene.

A touch sensor layer 400 may be located on the thin-film encapsulation layer 300. The touch sensor layer 400 may include a first touch-insulating layer 410, a second touch-insulating layer 420, a first conductive layer 430, a third touch-insulating layer 440, a second conductive layer 450, and a planarization layer 460.

In one or more embodiments, the first touch-insulating layer 410 may be located on the second inorganic encapsulation layer 330, and the second touch-insulating layer 420 may be located on the first touch-insulating layer 410. In one or more embodiments, each of the first touch-insulating layer 410 and the second touch-insulating layer 420 may include an inorganic insulating material and/or an organic insulating material. For example, each of the first touch-insulating layer 410 and the second touch-insulating layer 420 may include an inorganic insulating material, such as silicon oxide, silicon nitride, and/or silicon oxynitride.

In one or more embodiments, at least one of the first touch-insulating layer 410 or the second touch-insulating layer 420 may be omitted. For example, the first touch-insulating layer 410 may be omitted. In this case, the second touch-insulating layer 420 may be located on the second inorganic encapsulation layer 330, and the first conductive layer 430 may be located on the second touch-insulating layer 420.

The first conductive layer 430 may be located on the second touch-insulating layer 420, and the third touch-insulating layer 440 may be located on the first conductive layer 430. In one or more embodiments, the third touch-insulating layer 440 may include an inorganic insulating material and/or an organic insulating material. For example, the third touch-insulating layer 440 may include an inorganic insulating material, such as silicon oxide, silicon nitride, and/or silicon oxynitride.

The second conductive layer 450 may be located on the third touch-insulating layer 440. A touch electrode TE of an input-sensing layer may have a structure in which the first conductive line 430 and the second conductive line 450 are connected to each other. Alternatively, the touch electrode TE may be formed on any one of the first conductive layer 430 and the second conductive layer 450, and may include a metal line provided on the conductive layer. Each of the first conductive layer 430 and the second conductive layer 450 may include at least one of aluminum (Al), copper (Cu), titanium (Ti), molybdenum (Mo), or indium tin oxide (ITO), and may have a single or multi-layer structure including the above material. For example, each of the first conductive line 430 and the second conductive line 450 may have a three-layer structure including a titanium layer, an aluminum layer, and a titanium layer.

In one or more embodiments, the planarization layer 460 may cover the second conductive layer 450. The planarization layer 460 may include an organic insulating material.

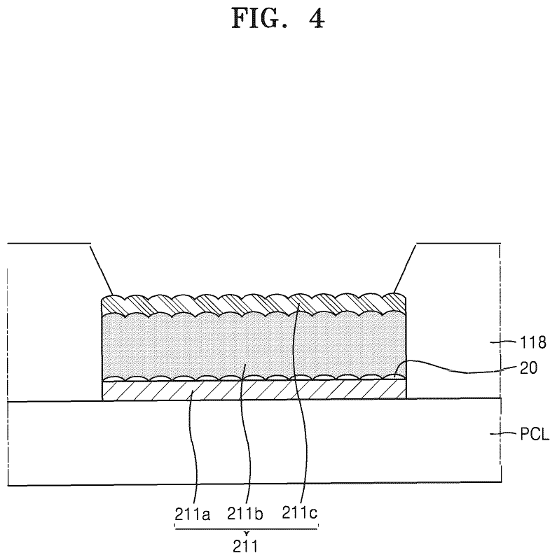

FIG. 4 is an enlarged cross-sectional view schematically illustrating a display panel, according to one or more embodiments.

Referring to FIG. 4, the pixel electrode 211 may be located on the pixel circuit layer PCL. Because the pixel circuit layer PCL includes the substrate 100 (see FIG. 3), the pixel electrode 211 may be located on the substrate 100.

The pixel electrode 211 may include a first pixel electrode 211a, a second pixel electrode 211b, and a third pixel electrode 211c. The second pixel electrode 211b may be located on the first pixel electrode 211a, and the third pixel electrode 211c may be located on the second pixel electrode 211b. In other words, the second pixel electrode 211b may be located between the first pixel electrode 211a and the third pixel electrode 211c.

In one or more embodiments, a thickness of the first pixel electrode 211a may be about 70 Å. A thickness of the second pixel electrode 211b may be about 700 Å. A thickness of the third pixel electrode 211c may be about 70 Å. However, the disclosure is not limited thereto.

The first pixel electrode 211a may be a transparent electrode. The first pixel electrode 211a may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

The second pixel electrode 211b may include a metal. The second pixel electrode 211b may include silver (Ag), magnesium (Mg), aluminum (Al), platinum (Pt), palladium (Pd), gold (Au), nickel (Ni), neodymium (Nd), iridium (Ir), chromium (Cr), or a compound thereof.

The third pixel electrode 211c may be a transparent electrode. The third pixel electrode 211c may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

A bottom surface of the first pixel electrode 211a may be flat. A top surface of the second pixel electrode 211b may have an uneven shape. A bottom surface of the second pixel electrode 211b may have an uneven shape. Metal nanoparticles 20 may be distributed on the bottom surface of the second pixel electrode 211b to form an uneven shape. A top surface of the third pixel electrode 211c may have an uneven shape.

The metal nanoparticles 20 may be distributed on the bottom surface of the second pixel electrode 211b to form an uneven shape. In a process of forming the second pixel electrode 211b and the third pixel electrode 211c on the metal nanoparticles 20, because the second pixel electrode 211b and the third pixel electrode 211c are formed by replicating the uneven shape of the metal nanoparticles 20 on the bottom surface of the second pixel electrode 211b, the top surface of the second pixel electrode 211b and the top surface of the third pixel electrode 211c may have uneven shapes. Although the top surface of the second pixel electrode 211b has an uneven shape, the metal nanoparticles 20 are not distributed on the top surface of the second pixel electrode 211b.

In a comparative example, to increase a viewing angle of a display apparatus, metal particles may be dispersed inside a reflective film included in a pixel electrode. In this case, because patterning may be performed to form the reflective film in which the metal particles are dispersed, and because patterning may be performed again to form a transparent electrode thereon during a manufacturing process, a mask may be increased, and the efficiency of the manufacturing process may be reduced. Also, because the metal particles aggregated and protruding on a surface of the reflective film are not be properly covered by the transparent electrode and an emission layer, there may be a portion where the emission layer does not exist between the pixel electrode and a counter electrode, thereby causing dark spots and reducing the luminance of the display apparatus.

In one or more embodiments, the top surface of the second pixel electrode 211b and the top surface of the third pixel electrode 211c included in the pixel electrode 211 may have uneven shapes to function as light scattering centers, thereby increasing a viewing angle of the display apparatus. Compared to the comparative example, because the top surface of the second pixel electrode 211b of one or more embodiments has an uneven shape, but the metal nanoparticles 20 are not distributed on the top surface of the second pixel electrode 211b, a stepped portion of the top surface of the second pixel electrode 211b may be reduced compared to the comparative example, and thus, the third pixel electrode 211c and the emission layer 212b (see FIG. 3) may efficiently cover the second pixel electrode 211b, and the luminance of the display apparatus may be improved. Also, because the second pixel electrode 211b and the third pixel electrode 211c are formed by replicating the uneven shape of the metal nanoparticles 20 located on the bottom surface of the first pixel electrode 211a, the second pixel electrode 211b and the third pixel electrode 211c may be formed without adding a mask, thereby improving the efficiency of a process of manufacturing the display apparatus.

A diameter of each of the metal nanoparticles 20 distributed on the bottom surface of the second pixel electrode 211b may be tens of nm to several μm. When a diameter of each of the metal nanoparticles 20 distributed on the bottom surface of the second pixel electrode 211b is less than tens of nm, the metal nanoparticles 20 may not function as a light-scattering center. When a diameter of each of the metal nanoparticles 20 distributed on the bottom surface of the second pixel electrode 211b is greater than several μm, the size of a pixel is tens of μm, and thus, the number of metal nanoparticles that may be distributed therein may not be sufficient, and the metal nanoparticles 20 may not function as a light-scattering center.

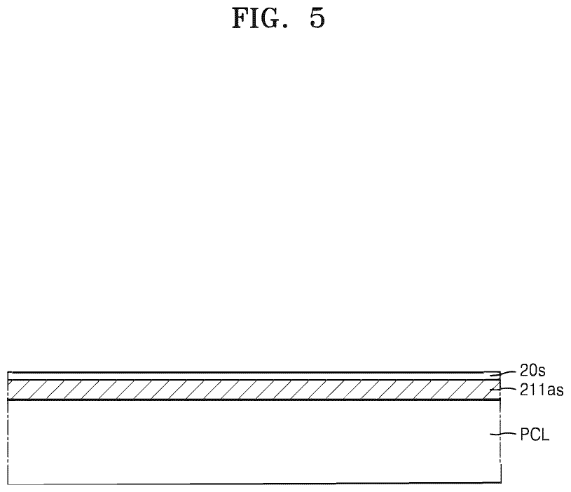

FIGS. 5 to 9 are cross-sectional views schematically illustrating a method of manufacturing a display panel, according to one or more embodiments.

Referring to FIG. 5, a first pixel electrode-forming material (e.g., first electrode material) 211as may be located on (e.g., above) the pixel circuit layer PCL. Because the pixel circuit layer PCL includes the substrate 100 (see FIG. 3), the first pixel electrode-forming material 211as may be located on the substrate 100. A bottom surface of the first pixel electrode-forming material 211as may be flat.

The first pixel electrode-forming material 211as may include a transparent electrode material. The first pixel electrode-forming material 211as may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

A metal nanoparticle-forming material (e.g., metal nanoparticle material) 20s may be located on the first pixel electrode-forming material 211as. The metal nanoparticle-forming material 20s may include silver (Ag), magnesium (Mg), aluminum (Al), platinum (Pt), palladium (Pd), gold (Au), nickel (Ni), neodymium (Nd), iridium (Ir), chromium (Cr), or a compound thereof.

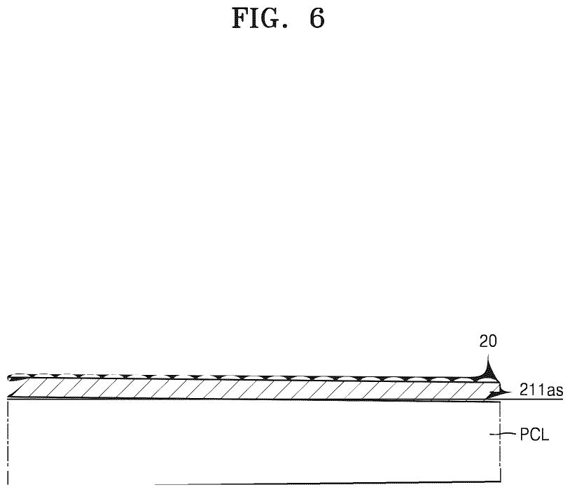

Referring to FIG. 6, the metal nanoparticles 20 may be formed on a top surface of the first pixel electrode-forming material 211as by heat-treating the metal nanoparticle-forming material 20s. When the metal nanoparticle-forming material 20s is heat-treated, the metal nanoparticle-forming material 20s may be aggregated to form the metal nanoparticles 20. In detail, conditions of a process of heat-treating the metal nanoparticle-forming material 20s may be conditions of heat-treating in a nitrogen (N₂) atmosphere at a temperature of about 250° C. for one hour.

The metal nanoparticles 20 may be distributed on the top surface of the first pixel electrode-forming material 211as to form an uneven shape. The metal nanoparticles 20 may be distributed on the top surface of the first pixel electrode-forming material 211as without being aggregated.

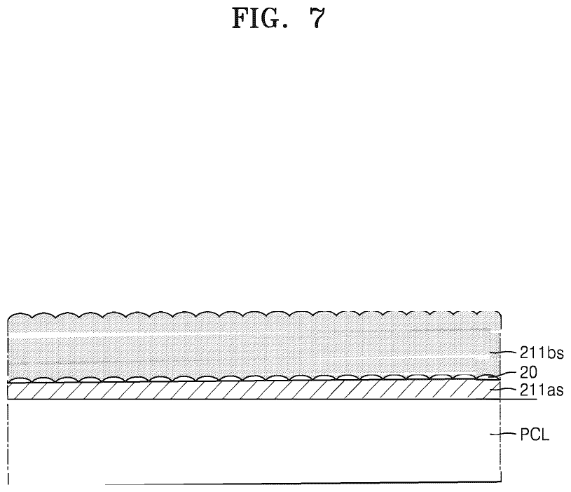

Referring to FIG. 7, a second pixel electrode-forming material (e.g., second pixel electrode material) 211bs may be located on the metal nanoparticles 20. The second pixel electrode-forming material 211bs may include a metal. In detail, the second pixel electrode-forming material 211bs may include silver (Ag), magnesium (Mg), aluminum (Al), platinum (Pt), palladium (Pd), gold (Au), nickel (Ni), neodymium (Nd), iridium (Ir), chromium (Cr), or a compound thereof. The second pixel electrode-forming material 211bs and the metal nanoparticle-forming material 20s may be the same.

The metal nanoparticles 20 may be distributed on a bottom surface of the second pixel electrode-forming material 211bs to form an uneven shape. Because the second pixel electrode-forming material 211bs is formed by replicating the uneven shape of the bottom surface of the second pixel electrode-forming material 211bs, a top surface of the second pixel electrode-forming material 211bs may have an uneven shape.

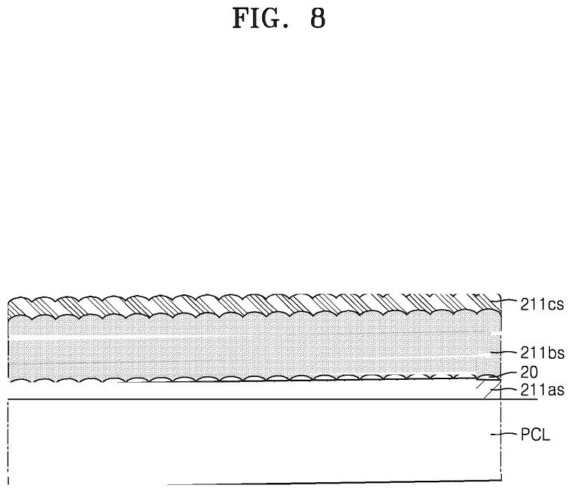

Referring to FIG. 8, a third pixel electrode-forming material (e.g., third pixel electrode material) 211cs may be located on the second pixel electrode-forming material 211bs. The third pixel electrode-forming material 211cs may include a transparent electrode material. The third pixel electrode-forming material 211cs may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO).

A top surface of the third pixel electrode-forming material 211cs may have an uneven shape. Because the third pixel electrode-forming material 211cs is formed by replicating the uneven shape formed on the top surface of the second pixel electrode-forming material 211b, the top surface of the third pixel electrode-forming material 211cs may have an uneven shape.

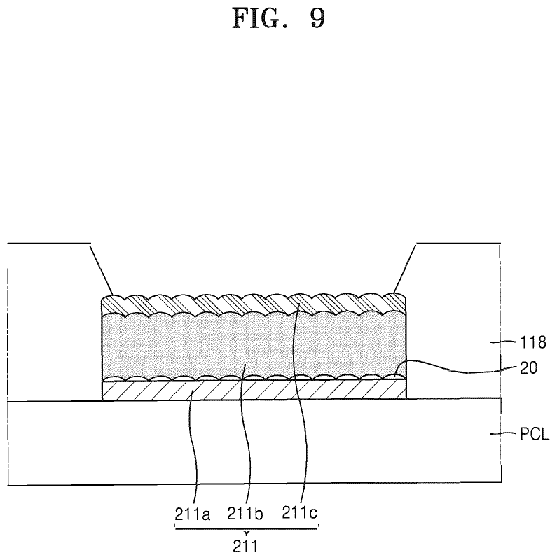

Referring to FIG. 9, the first pixel electrode 211a, the second pixel electrode 211b, and the third pixel electrode 211c may be formed by etching the first pixel electrode-forming material 211as, the second pixel electrode-forming material 211bs, and the third pixel electrode-forming material 211cs. In detail, the first pixel electrode 211a, the second pixel electrode 211b, and the third pixel electrode 211c may be formed by wet etching the first pixel electrode-forming material 211as, the second pixel electrode-forming material 211bs, and the third pixel electrode-forming material 211cs.

A bottom surface of the first pixel electrode 211a may be flat. A bottom surface and a top surface of the second pixel electrode 211b may have uneven shapes. A top surface of the third pixel electrode 211c may have an uneven shape. The metal nanoparticles 20 may be distributed on the bottom surface of the second pixel electrode 211b to form an uneven shape.

In one or more embodiments, because the metal nanoparticles 20 are formed and then the second pixel electrode-forming material 211bs and the third pixel electrode-forming material 211cs are formed by replicating the uneven shape formed by the metal nanoparticles 20, the top surfaces of the second pixel electrode 211b and the third pixel electrode 211c may have uneven shapes, and may function as light-scattering centers, thereby increasing a viewing angle, without adding a mask, and increasing the efficiency of a process of manufacturing the display apparatus compared to the comparative example.

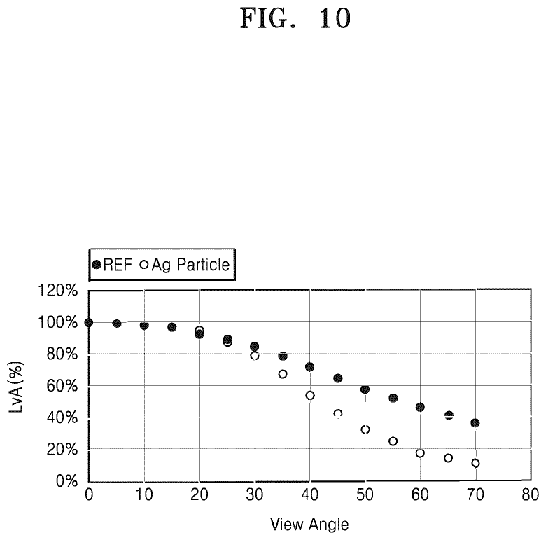

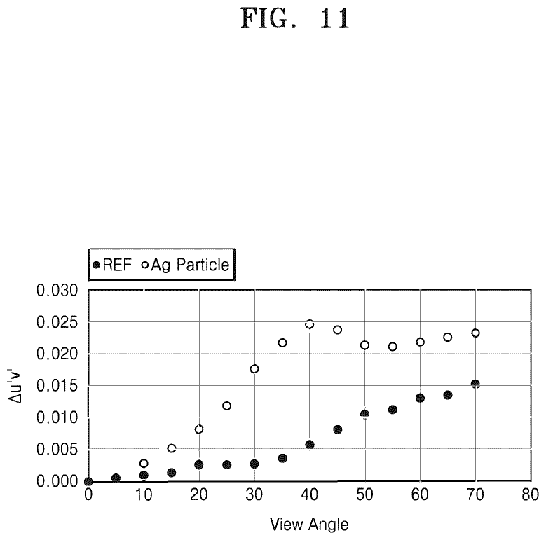

FIG. 10 is a graph schematically illustrating a luminance according to a viewing angle, according to a comparative example and one or more embodiments. FIG. 11 is a graph schematically illustrating color coordinates according to a viewing angle, according to a comparative example and one or more embodiments.

Referring to FIG. 10, it is found that a difference in a luminance according to a viewing angle is small in the disclosed embodiments, as compared to the comparative example. It is found that uneven shapes formed on top surfaces of the second pixel electrode 211b (see FIG. 4) and the third pixel electrode 211c (see FIG. 4) function as light-scattering centers to increase a viewing angle.

Referring to FIG. 11, it is found that a difference in color coordinates according to a viewing angle is small in the disclosed embodiments compared to the comparative example. It is found that uneven shapes formed on top surfaces of the second pixel electrode 211b (see FIG. 4) and the third pixel electrode 211c (see FIG. 4) function as light-scattering centers to increase a viewing angle without a color change.

According to one or more embodiments, as described above, a display apparatus with improved reliability and quality and a method of manufacturing the display apparatus may be provided. However, the scope of the disclosure is not limited by this effect.

It should be understood that embodiments described herein should be considered in a descriptive sense only, and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display apparatus comprising:
a substrate; and
a pixel electrode above the substrate and comprising:
a first pixel electrode above the substrate, and having a bottom surface that is flat;
a second pixel electrode above the first pixel electrode, and having a top surface that has an uneven shape; and
a third pixel electrode above the second pixel electrode, and having a top surface that has an uneven shape.

2. The display apparatus of claim 1, wherein a bottom surface of the second pixel electrode has an uneven shape.

3. The display apparatus of claim 2, further comprising metal nanoparticles distributed on the bottom surface of the second pixel electrode to form the uneven shape.

4. The display apparatus of claim 3, wherein a diameter of the metal nanoparticles is tens of nm to several μm.

5. The display apparatus of claim 1, wherein the first pixel electrode comprises a transparent electrode.

6. The display apparatus of claim 1, wherein the third pixel electrode comprises a transparent electrode.

7. The display apparatus of claim 1, wherein the second pixel electrode comprises a metal.

8. The display apparatus of claim 7, wherein the second pixel electrode comprises silver (Ag).

9. A method of manufacturing a display apparatus, the method comprising:
arranging a first pixel electrode material above a substrate;
arranging metal nanoparticles above the first pixel electrode material;
arranging a second pixel electrode material above the metal nanoparticles;
arranging a third pixel electrode material above the second pixel electrode-forming material; and
forming a first pixel electrode, a second pixel electrode, and a third pixel electrode by etching the first pixel electrode material, the second pixel electrode material, and the third pixel electrode material.

10. The method of claim 9, wherein the metal nanoparticles are distributed on a bottom surface of the second pixel electrode material to form an uneven shape.

11. The method of claim 9, wherein the arranging of the metal nanoparticles on the first pixel electrode material comprises:
arranging a metal nanoparticle material on the first pixel electrode material; and
forming the metal nanoparticles on a top surface of the first pixel electrode material by heat-treating the metal nanoparticle-forming material.

12. The method of claim 11, wherein the heat-treating the metal nanoparticle material causes the metal nanoparticle material to aggregate to form nanoparticles.

13. The method of claim 9, wherein a top surface of the second pixel electrode material has an uneven shape.

14. The method of claim 9, wherein a top surface of the third pixel electrode material has an uneven shape.

15. The method of claim 9, wherein a bottom surface of the first pixel electrode material has a flat shape.

16. The method of claim 9, wherein the first pixel electrode material comprises a transparent electrode material.

17. The method of claim 11, wherein the metal nanoparticle material and the second pixel electrode material comprise a same material.

18. The method of claim 17, wherein the second pixel electrode material comprises a metal.

19. The method of claim 9, wherein the third pixel electrode material comprises a transparent electrode material.

20. An electronic device comprising a display apparatus comprising:
a substrate; and
a pixel electrode above the substrate and comprising:
a first pixel electrode above the substrate, and having a bottom surface that is flat;
a second pixel electrode above the first pixel electrode, and having a top surface that has an uneven shape; and
a third pixel electrode above the second pixel electrode, and having a top surface that has an uneven shape.
